(19) United States
(12) Patent Application Publication
(10) Pub. No.: US 2020/0292221 A1
(43) Pub. Date: Sep. 17, 2020

(54) PHASE-CHANGE COOLING SYSTEM AND METHOD FOR CONTROLLING THE SAME

(71) Applicant: NEC CORPORATION, Tokyo (JP)

(72) Inventors: Hisato SAKUMA, Tokyo (JP); Minoru YOSHIKAWA, Tokyo (JP); Masaki CHIBA, Tokyo (JP)

(73) Assignee: NEC CORPORATION, Tokyo (JP)

(21) Appl. No.: 16/892,770

(22) Filed: Jun. 4, 2020

Related U.S. Application Data
(62) Division of application No. 15/761,150, filed on Mar. 19, 2018.

(30) Foreign Application Priority Data
Sep. 25, 2015 (JP) 2015-188224

(51) Int. Cl. F25B 49/02; H01L 23/427; H05K 7/20; F25B 23/00; F25B 5/02; F25B 41/04

(52) U.S. Cl. CPC F25B 49/02; H01L 23/427; F25B 41/04; F25B 23/006; F25B 5/02; H05K 7/2029

(57) ABSTRACT

A phase-change cooling system including: an evaporator holding a refrigerant liquid receiving heat from a heat generating source; a condenser releasing heat of a refrigerant vapor generated by vaporization of the refrigerant liquid at the evaporator and generating the refrigerant liquid; refrigerant liquid driving unit circulating the refrigerant liquid; a first piping unit for connecting the evaporator and the condenser; a second piping unit connecting the condenser and the refrigerant liquid driving unit; a third piping unit connecting the refrigerant liquid driving unit and the evaporator; and a fourth piping unit having one end connected to the first piping unit at a first connection point and another end connected to the second piping unit at a second connection point; a refrigerant storage unit storing the refrigerant liquid, the refrigerant storage unit being provided within a flow channel formed with the second piping unit.

### CROSS-REFERENCE TO RELATED APPLICATIONS

This application is a divisional of U.S. application Ser. No. 15/761,150, filed Mar. 19, 2018, which is a National Stage Entry of PCT/JP2016/004296, filed Sep. 21, 2016, which is based on and claims priority under 35 USC 119 from Japanese Patent Application No. 2015-188224 filed Sep. 25, 2015, each of which is incorporated herein by reference in its entirety.

### TECHNICAL FIELD

The present invention relates to a phase-change cooling system and a control method thereof for cooling an electronic device and the like, and particularly relates to a phase-change cooling system and a control method thereof that circulate a refrigerant liquid using a driving source.

### BACKGROUND ART

In recent years, as a size of an electronic device becomes small and a performance of the electronic device becomes high, the calorific power and the heat generation density of the electronic device increase. To effectively cool such electronic device and the like, it is necessary to adopt a cooling system having a high cooling performance. As one of the cooling system having the high cooling performance, attentions are focused to a phase change cooling system using the phase-change of the refrigerant.

PTL 1 discloses one example of the cooling system (phase-change cooling system) by the phase change cooling system. A cooling module for electronic device disclosed in PTL 1 is a pump circulation type phase-change cooling system and includes a cooling fluid drive unit formed from a jacket (evaporator) that is thermally connected with the heating generating object and absorbs the heat, the radiator, the tank that has a gas-liquid separation function, and the electric pump.

To an inlet of this jacket, a pipe through which the refrigerant flows in liquid form is provided, and to an outlet of the jacket, a pipe through which the gas-liquid mixture flows is provided respectively. At in front of the inlet pipe of the jacket, the cooling fluid drive unit is installed, and in the vicinity of the outlet of the jacket, the tank that has a gas-liquid separation function is connected. The refrigerant vapor separated at this tank flows into the steam pipe, thereafter, at the radiator, is condensed, and via the piping, returns to the cooling fluid drive unit to form a closed loop of the refrigerant.

The tank that has a gas-liquid separation function is partitioned, by the porous body, into an area in which a refrigerant liquid is retained and a gas-liquid mixing area in which the refrigerant in a gas-liquid mixing state inhaled from the jacket is present. The area in which the refrigerant liquid is retained is, via the bypass pipe, connected between the radiator and the cooling fluid drive means.

By the above configuration, according to the related-art cooling module (phase-change cooling system), it is possible to prevent the refrigerant liquid from adhering within the piping that is provided between the jacket and the radiator. As a result, it is possible to reduce the pressure loss between the jacket and the radiator and conduct the efficient cooling.

Further, another related art is a technique disclosed in PTL 2.

### CITATION LIST

### Patent Literature

[PTL 1] Japanese Unexamined Patent Application Publication No. 2008-130746 A (paragraphs [0021] to [0036], and FIG. 1)
[PTL 2] International Publication No. WO 2015/075916

### SUMMARY OF INVENTION

### Technical Problem

FIG. 4A illustrates a typical configuration example of a pump circulation type phase-change cooling system that circulates the refrigerant liquid using the driving source such as the pump as the above described related-art phase-change cooling system. A related-art phase-change cooling system 500 illustrated in FIG. 4A includes an evaporator 510 such as a radiator, a condenser 520 such as the heat exchanger and the outdoor unit, a driving source 530 such as the pump, a steam pipe 540, and a liquid pipe 550. The related-art phase-change cooling system 500, using a pump P or the like, supplies a refrigerant liquid LR to the evaporator 510, and the evaporator 510 receives the heat by the latent heat when the refrigerant liquid LR is evaporated and causes a refrigerant vapor VR to be generated. The refrigerant vapor VR emitted from the evaporator 510 releases the heat, at the condenser 520, is condensed, returns to the refrigerant liquid LR, and via the liquid pipe 550, is sent to the driving source 530 such as the pump P.

However, the pump circulation type phase-change cooling system of this type has an issue that immediately after the pump circulation type phase-change cooling system is started up, the cooling performance thereof is substantially lowered. Reasons thereof are described below.

In the pump circulation type phase-change cooling system, when a pump is stopped, the refrigerant liquid is accumulated in the evaporator and the steam pipe by the action of the gravity. Thereafter, when the pump circulation type phase-change cooling system is started up again, by the pressure of a liquid column of refrigerant liquid accumulated in the steam pipe, the evaporation of the refrigerant liquid in the evaporator is suppressed, and thus, the evaporator receives the heat by the sensible heat of the refrigerant liquid. The refrigerant that flows into the condenser in the liquid-phase state is cooled at the condenser and is refluxed to the evaporator. Thus, since the temperature of the refrigerant liquid does not rise up to the boiling point, the cooling is conducted at the evaporator not by the latent heat by the evaporation but by the sensible heat by the refrigerant liquid. Generally, the efficiency of the reception of the heat by the sensible heat is lower than the efficiency of the reception of the heat by the latent heat, and thus, in such a case, the cooling performance of the pump circulation type phase-change cooling system is substantially lowered.

Issues of the above described pump circulation type phase-change cooling system are described further in details.

FIG. 4A schematically illustrates a distribution state of the refrigerant liquid LR and the refrigerant vapor VR when the above described related-art pump circulation type phase-change cooling system 500 is normally operated. As described above, when the cooling system is normally operated, the refrigerant liquid LR is supplied, via the pump P, to the evaporator 510, evaporates at the evaporator 510 and becomes the refrigerant vapor VR. The refrigerant vapor VR is, via the steam pipe 540, transported to the condenser 520, at the condenser 520, is cooled and condensed, and becomes the refrigerant liquid LR. This refrigerant liquid LR passes the liquid pipe 550 and again is supplied to the pump P. As above, when the cooling system is normally operated, in the evaporator 510 of a phase-change cooling system 500, the heat is taken by the evaporation of the refrigerant liquid LR, and thus, the cooling efficiency is high. When the cooling system is normally operated, as schematically illustrated in FIG. 4A, the steam pipe 540 is filled with the refrigerant vapor VR, and the liquid pipe 550 is filled with the refrigerant liquid LR.

FIG. 4B schematically illustrates the distribution of the refrigerant when the pump P is stopped. Here, a stopped state indicates a state in which the pump P and the circulation of the refrigerant are both stopped. At this time, the refrigerant liquid LR, by the action of gravity, accumulates at a lower place. FIG. 4B illustrates a case where the gas-liquid interface INT of the refrigerant is present between the evaporator 510 and the condenser 520 in the vertical direction, and the steam pipe 540 and the liquid pipe 550 are respectively filled with both of the refrigerant liquid LR and the refrigerant vapor VR.

Next, FIGS. 5A and 5B schematically illustrate the distribution of the refrigerant when the pump P is started up from the stopped state. FIG. 5A illustrates a case where an amount of the refrigerant is small and FIG. 5B illustrates a case where an amount of the refrigerant is large respectively.

When an amount of the refrigerant is small as illustrated in FIG. 5A, the refrigerant liquid LR at a suction side of the pump P is not present, and thus, the circulation of the refrigerant is stopped. Immediately after starting up the pump P, at the evaporator 510, the heat absorbing by the sensible heat of the refrigerant liquid LR occurs. At this time, since the circulation of the refrigerant liquid LR does not occur, the temperature of the refrigerant liquid LR rises. However, by the pressure of the refrigerant liquid LR accumulated in the steam pipe 540, since the boiling point of the refrigerant liquid rises, before the temperature of the refrigerant liquid LR within the evaporator 510 reaches the boiling point, there is a case where the temperature of the refrigerant liquid is equal to the temperature of the heat generating object that is a target of heat absorption. As a result, the evaporator 510 stops absorbing the heat.

On the other hand, when an amount of the refrigerant is large as illustrated in FIG. 5B, the refrigerant liquid LR, via the condenser 520, circulates. However, since the refrigerant liquid LR is cooled at the condenser 520, at the evaporator 510, the temperature of the refrigerant liquid does not rise up to the boiling point, and the evaporation does not occur. Thus, since the heat is received only by the sensible heat of the refrigerant liquid LR, the cooling efficiency is substantially lowered.

As described above, regardless of whether an amount of the refrigerant is large or small, it is difficult to start up the pump P from the stopped state and move the state of the pump P to the normal operation state (FIG. 4A) and immediately after starting up the pump P, the cooling performance is substantially lowered.

As describe above, the phase-change cooling system that circulates the refrigerant liquid using the driving source has had an issue that immediately after the startup, the cooling performance is substantially lowered.

An object of the present invention is to provide a phase-change cooling system and a control method thereof that solve the above described issue in which a cooling performance of the phase-change cooling system that circulates the refrigerant liquid using the driving source is substantially lowered immediately after the startup.

### Solution to Problem

An phase-change cooling system of the present invention includes: an evaporator that holds a refrigerant liquid receiving heat from a heat generating source; a condenser that releases heat of a refrigerant vapor generated by vaporization of the refrigerant liquid at the evaporator and generates the refrigerant liquid; refrigerant liquid driving means for circulating the refrigerant liquid, a first piping unit for connecting the evaporator and the condenser, a second piping unit for connecting the condenser and the refrigerant liquid driving means, a third piping unit for connecting the refrigerant liquid driving means and the evaporator, and a fourth piping unit having one end connected to the first piping unit at a first connection point and the other end connected to the second piping unit at the second connection point, wherein the first connection point is positioned at a lower place than a position of an interface between the refrigerant liquid and the refrigerant vapor in the first piping unit at the time when the refrigerant liquid driving means is started up.

A control method of a phase-change cooling system of the present invention, the phase-change cooling system including an evaporator that holds a refrigerant liquid receiving heat from a heat generating source, a condenser that releases heat of a refrigerant vapor generated by vaporization of the refrigerant liquid in the evaporator and generates the refrigerant liquid, refrigerant liquid driving means for circulating the refrigerant liquid, a first piping unit for connecting the evaporator and the condenser, a second piping unit for connecting the condenser and the refrigerant liquid driving means, a third piping unit for connecting the refrigerant liquid driving means and the evaporator, and a fourth piping unit having one end connected to the first piping unit at the first connection point and the other end connected to the second piping unit at the second connection point, the control method including controlling the phase-change cooling system in such a way that a position of an interface between the refrigerant liquid and the refrigerant vapor retained in the first piping unit at the time when the refrigerant liquid driving means is started up is positioned above the first connection point.

### Advantageous Effects of Invention

According to the phase-change cooling system and the control method thereof of the present invention, even with a configuration of circulating the refrigerant liquid using the driving source, the decrease in the cooling performance immediately after the startup can be avoided.

### BRIEF DESCRIPTION OF DRAWINGS

FIG. 1A is a schematic drawing schematically illustrating a configuration of a phase-change cooling system according to a first embodiment of the present invention.

FIG. 1B is a schematic drawing schematically illustrating a circulation state of a refrigerant in the phase-change cooling system according to the first embodiment of the present invention.

FIG. 1C is a schematic drawing schematically illustrating a state of the refrigerant in the phase-change cooling system according to the first embodiment of the present invention and illustrates a case where a refrigerant liquid driving unit of the phase-change cooling system is in a stopped state.

FIG. 2 is a schematic drawing schematically illustrating a configuration of a phase-change cooling system according to a second embodiment of the present invention.

FIG. 3 is a schematic drawing schematically illustrating a configuration of a phase-change cooling system according to a third embodiment of the present invention.

FIG. 4A is a drawing schematically illustrating a configuration of the related-art phase-change cooling system and distribution of a refrigerant when the cooling system is normally operated.

FIG. 4B is a drawing schematically illustrating a configuration of the related-art phase-change cooling system and distribution of the refrigerant when a pump is stopped.

FIG. 5A is a drawing schematically illustrating the distribution of the refrigerant when, in the related-art phase-change cooling system, the pump is started up from the stopped state and illustrates a case where an amount of the refrigerant is small.

FIG. 5B is a drawing schematically illustrating the distribution of the refrigerant when, in the related-art phase-change cooling system, the pump is started up from the stopped state and illustrates a case where an amount of the refrigerant is large.

### DESCRIPTION OF EMBODIMENTS

The embodiments of the present invention are described below with reference to the drawings.

### First Embodiment

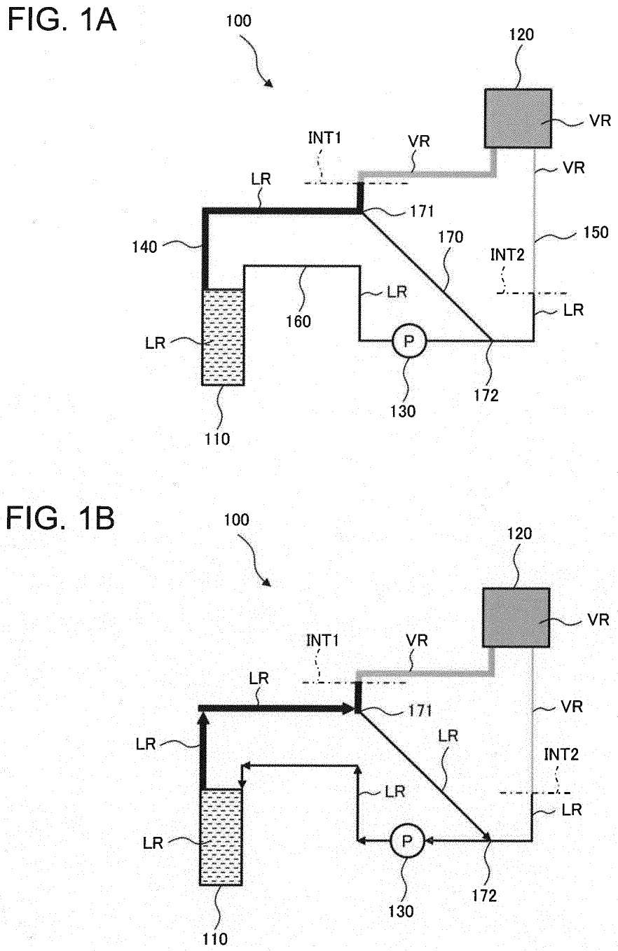

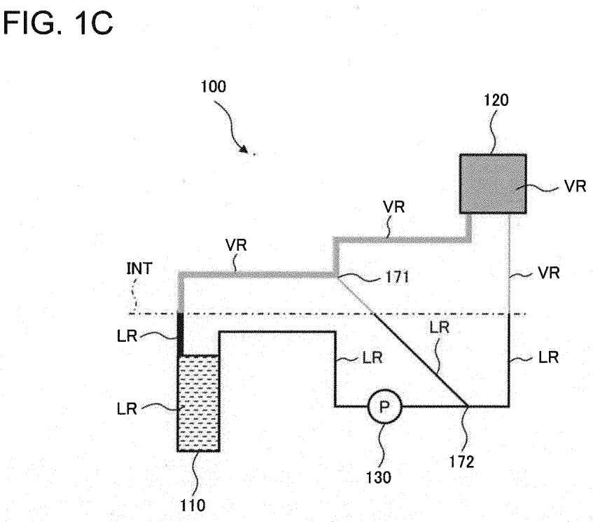

FIG. 1A is a schematic drawing schematically illustrating a configuration of a phase-change cooling system 100 according to the first embodiment of the present invention. Further, FIG. 1B is a schematic drawing schematically illustrating the circulation state of a refrigerant in the phase-change cooling system 100 according to the present embodiment.

The phase-change cooling system 100 according to the present embodiment, as illustrated in FIG. 1A, includes an evaporator 110, a condenser 120, and a refrigerant liquid driving unit (refrigerant liquid driving means) 130. Further, the phase-change cooling system 100 includes a first piping unit 140, a second piping unit 150, a third piping unit 160 and a fourth piping unit 170.

The evaporator 110 holds a refrigerant liquid LR that receives the heat from a heat generating source. The evaporator 110 is typically formed from a radiator and the like. The condenser 120 releases the heat of a refrigerant vapor VR generated by the vaporization of the refrigerant liquid LR at the evaporator 110 and generates the refrigerant liquid LR. The condenser 120 is typically formed from a heat exchanger, an outdoor unit and the like. Further, the refrigerant liquid driving unit 130 circulates the refrigerant liquid LR. The refrigerant liquid driving unit 130 is typically formed from a pump P and the like.

The first piping unit 140 connects the evaporator 110 and the condenser 120. The second piping unit 150 connects the condenser 120 and the refrigerant liquid driving unit 130. The third piping unit 160 connects the refrigerant liquid driving unit 130 and the evaporator 110.

One end of the fourth piping unit 170 is connected to the first piping unit 140 at a first connection point 171, and the other end of the fourth piping unit 170 is connected to the second piping unit 150 at a second connection point 172. Here, the first connection point 171 is positioned at a lower place than a position (INT1) of an interface between the refrigerant liquid LR and the refrigerant vapor VR within the first piping unit 140 at the time when the refrigerant liquid driving unit 130 is started up.

Note that the first piping unit 140, the second piping unit 150, the third piping unit 160 and the fourth piping unit 170 are typically formed from the metal piping and the like.

Arrows in FIG. 1B represent the refrigerant liquid LR that circulates within the phase-change cooling system 100 at the time when the refrigerant liquid driving unit 130 is started up. Here, the time of the startup of the refrigerant liquid driving unit 130 corresponds to a state in which the refrigerant liquid driving unit 130 is operated and also the refrigerant liquid LR held in the evaporator 110 does not receive the heat from the heat generating source.

As described above, the phase-change cooling system 100 according to the present embodiment includes the fourth piping unit 170 that is, at the first connection point 171, connected to the first piping unit 140 and, at the second connection point 172, connected to the second piping unit 150 respectively. Further, the first connection point 171 is configured to be positioned at a lower place than the position of the interface (INT1) between the refrigerant liquid LR and the refrigerant vapor VR within the first piping unit 140 at the time when the refrigerant liquid driving unit 130 is started up.

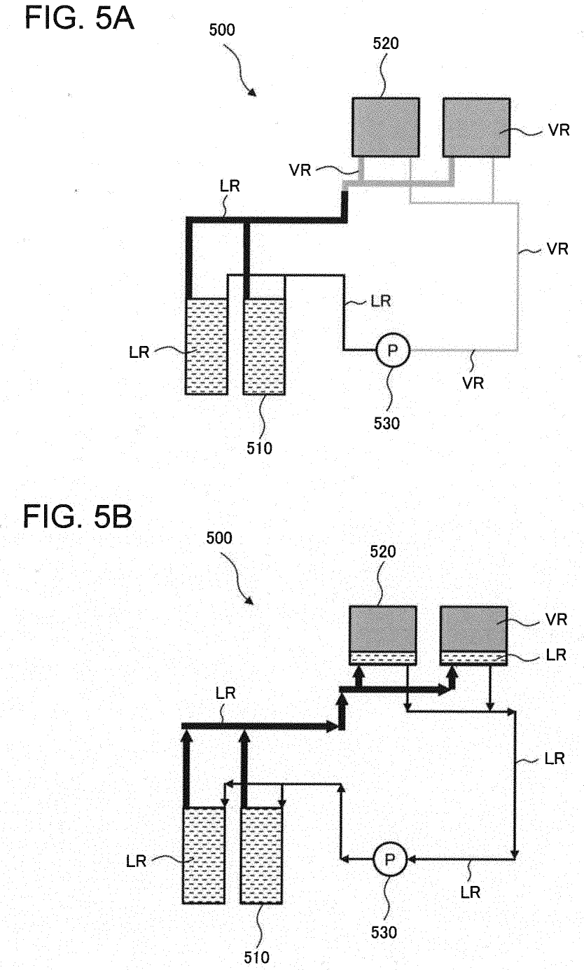

By the above configuration, even when an amount of the refrigerant is small as illustrated in FIG. 5A, the refrigerant liquid LR within the first piping unit 140 is, via the fourth piping unit 170, supplied to the refrigerant liquid driving unit 130. Thus, since the circulation of the refrigerant liquid LR can be continued, the state can be shifted to the normal operation state.

Further, even when an amount of the refrigerant is large as illustrated in FIG. 5B, the refrigerant liquid LR can, via the fourth piping unit 170, circulate. Thus, by the circulation of the refrigerant liquid LR, via the condenser 120, the refrigerant liquid LR is cooled, thereby making it possible to avoid a state in which at the evaporator 110, the evaporation of the refrigerant liquid LR does not occur. As a result, the state can be shifted to the normal operation state.

In the phase-change cooling system 100 in the normal operation state, the refrigerant liquid driving unit 130 supplies the refrigerant liquid LR to the evaporator 110 and, at the evaporator 110, the refrigerant liquid LR receives the heat from the heat generating source so that the temperature of the refrigerant liquid rises and reaches the boiling point. At this time, the heat is received from the heat generating source since by the latent heat at the time when the refrigerant liquid LR evaporates and becomes the refrigerant vapor VR. This enables the efficient heat reception. The refrigerant vapor VR generated at the evaporator 110 passes the first piping unit 140 and flows into the condenser 120, and by releasing the heat of the refrigerant vapor at the condenser 120, the refrigerant vapor is condensed and becomes the refrigerant liquid LR.

The refrigerant liquid LR that is condensed at the condenser 120 passes the second piping unit 150 and flows into the refrigerant liquid driving unit 130. In other words, the refrigerant liquid LR flows by passing the second piping unit 150 that is provided between the condenser 120 and the second connection point 172. Thus, an amount of the refrigerant liquid LR at the first piping unit 140 decreases, the pressure by the liquid column is lowered, and thus, the evaporation of the refrigerant liquid LR at the evaporator 110 is facilitated. As a result, the state of the phase-change cooling system 100 can be easily shifted to the normal operation state.

The refrigerant liquid driving unit 130 supplies the condensed refrigerant liquid LR, via the third piping unit 160, to the evaporator 110 again. Accordingly, the phase change cooling cycle by the refrigerant is completed, and the phase change cooling having the high cooling performance is realized.

As described above, according to the phase-change cooling system 100 of the present embodiment, regardless of whether an amount of the refrigerant is large or small, it is possible to start up the refrigerant liquid driving unit 130 from the stopped state and to shift the state of the phase-change cooling system to the normal operation state. Thus, even with the configuration of circulating the refrigerant liquid using the driving source such as the refrigerant liquid driving unit 130, the decrease in the cooling performance immediately after the startup can be avoided.

Further, according to the phase-change cooling system 100 of the present embodiment, the refrigerant liquid LR that is present within the first piping unit 140 when the cooling system is normally operated can be, by the fourth piping unit 170, refluxed to the second piping unit 150. As a result, the pressure drop of the first piping unit 140 can be decreased, and thus, the decrease in the cooling performance when the cooling system is normally operated can also be suppressed.

FIGS. 1A and 1B illustrate a configuration in which the second connection point 172 of the fourth piping unit 170 is positioned at a lower place than a position of the interface (INT2) between the refrigerant liquid LR and the refrigerant vapor VR retained in the second piping unit 150 at the time when the refrigerant liquid driving unit 130 is started up. Further, all of the positions of the interfaces between the refrigerant liquid LR and the refrigerant vapor VR at the time when the refrigerant liquid driving unit 130 is started up (INT1, INT2) can be configured to be positioned at lower places than the condenser 120. This enables the refrigerant liquid LR to circulate by passing the fourth piping unit 170, and thus, it is possible to prevent the refrigerant liquid LR from refluxing to the refrigerant liquid driving unit 130 via the condenser 120. As described above, the refrigerant liquid LR is cooled when the refrigerant liquid LR passes the condenser 120, and this may prevent the temperature of the refrigerant liquid LR from rising up to the boiling point at the evaporator 110. With the above described configuration, it is possible to avoid such influences, and thereby achieving the efficient cooling.

Note that when the refrigerant liquid driving unit 130 is in the stopped state, the gas-liquid interface INT between the refrigerant liquid LR and the refrigerant vapor VR only needs to be, as illustrated in FIG. 1C, provided above the refrigerant liquid driving unit 130.

Further, the first connection point 171 of the fourth piping unit 170 may be configured to be positioned above the second connection point 172. With the above configuration, the refrigerant liquid LR that flows from the first connection point 171 to the fourth piping unit 170 can, by the action of gravity, flow to the second connection point 172. Thus, the workload of the refrigerant liquid driving unit 130 can be reduced.

Further, the condenser 120 may be configured to be positioned above the evaporator 110 and the refrigerant liquid driving unit 130. Accordingly, since the natural circulation of the refrigerant by the action of gravity can also be used, the workload of the refrigerant liquid driving unit 130 can be reduced.

Note that the first connection point 171 at which the fourth piping unit 170 is connected to the first piping unit 140 is preferably positioned in the vicinity of the evaporator 110. This is because the pressure exerted on the refrigerant liquid LR within the evaporator 110 by the liquid column of the refrigerant liquid LR accumulated in the first piping unit 140 is proportional to the height of the first connection point 171 from the top of the evaporator 110. By positioning the first connection point 171 in the vicinity of the evaporator 110, the height of the first connection point 171 can be reduced, and accordingly the pressure rise by the liquid column of the refrigerant liquid LR can be suppressed. As a result, as described above, a problem that the evaporation of the refrigerant liquid LR does not occur because the boiling point of the refrigerant liquid rises due to the pressure rise of the refrigerant liquid LR can be prevented.

Next, a control method of the phase-change cooling system according to the present embodiment is described.

A configuration of a phase-change cooling system is similar to the configuration of the above described phase-change cooling system 100. This phase-change cooling system is controlled such that a position (INT1) of the interface between the refrigerant liquid LR and the refrigerant vapor VR retained in the first piping unit 140 at the time when the refrigerant liquid driving means 130 is started up is positioned above the first connection point 171.

By controlling the phase-change cooling system 100 in this manner, as described above, even with the configuration in which the refrigerant liquid is circulated using the driving source such as the refrigerant liquid driving means 130, the decrease in the cooling performance immediately after the startup can be avoided.

### Second Embodiment

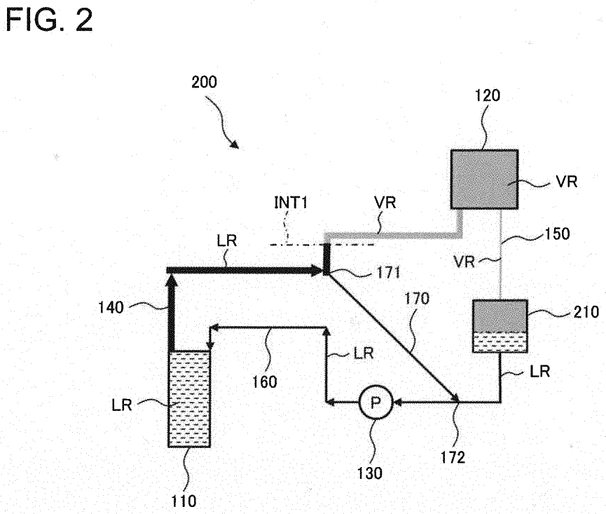

Next, the second embodiment of the present invention is described. FIG. 2 schematically illustrates a configuration of a phase-change cooling system 200 according to the second embodiment of the present invention. Arrows in FIG. 2 represent the refrigerant liquid LR that circulates within the phase-change cooling system 200 at the time when the refrigerant liquid driving unit 130 is started up.

The phase-change cooling system 200 according to the present embodiment includes an evaporator 110, a condenser 120 and a refrigerant liquid driving unit 130. The phase-change cooling system 200 further includes a first piping unit 140, a second piping unit 150, a third piping unit 160 and a fourth piping unit 170. The configuration of the phase-change cooling system 200 above is similar to the configuration of the phase-change cooling system 100 according to the first embodiment.

The phase-change cooling system 200 according to the present embodiment further includes, in a flow channel formed from the second piping unit 150, a refrigerant storage unit (refrigerant storage means) 210 for storing the refrigerant liquid LR. The refrigerant storage unit 210 is typically formed from a metal container such as a tank.

Here, the refrigerant storage unit 210 may be configured to be positioned above the refrigerant liquid driving unit 130. Further, the refrigerant storage unit 210 may be configured such that the interface between the refrigerant liquid LR and the refrigerant vapor VR when the refrigerant liquid driving unit 130 is stopped is positioned at a lower place than the top of the refrigerant storage unit 210. In other words, the refrigerant storage unit 210 may be configured to be positioned such that when the refrigerant liquid driving unit 130 is in the stopped state, the refrigerant storage unit 210 is not filled only with the refrigerant liquid LR.

Further, the refrigerant storage unit 210 may be configured to be positioned at a lower place than the first connection point 171. Accordingly, the reflux of the refrigerant liquid LR from the refrigerant storage unit 210 to the first piping unit 140 can be prevented. Next, effects by the phase-change cooling system 200 according to the present embodiment are described.

Since the phase-change cooling system 200 according to the present embodiment is configured to include the refrigerant storage unit 210, even when the state of the cooling system is shifted to the normal operation state, it is possible to prevent a problem that the heat receiving amount at the evaporator 110 decreases because an amount of the refrigerant liquid is too large. Further, an effect of securing the liquid column pressure for supplying the refrigerant liquid to the refrigerant liquid driving unit 130 formed from the pump and the like can be achieved.

The above described effect of avoiding the influence of the too large amount of the refrigerant liquid is further described in details.

In the phase-change cooling system, there exists the proper refrigerant amount at which the heat receiving amount is maximized at the evaporator in the normal operation state. With respect to the above, descriptions are given below. When the phase-change cooling system is normally operated, to increase the heat receiving amount at the evaporator, it is necessary to reduce the pressure of the refrigerant at the evaporator. This is because, if the pressure of the refrigerant at the evaporator increases, the boiling point T_{V} of the refrigerant rises. In other words, generally, when the heat from the heat source of the certain temperature Tₕₑₐₜ is received at the evaporator, as the difference Tₕₑₐₜ-T_{V} between the temperature of the heat from the heat source and the boiling point of the refrigerant liquid becomes larger, the boiling of the refrigerant liquid is facilitated further, and thus, the heat receiving amount at the evaporator becomes large. Accordingly, if the pressure of the refrigerant at the evaporator increases and the boiling point T_{V} of the refrigerant rises, Tₕₑₐₜ-T_{V} decreases, and the heat receiving amount decreases.

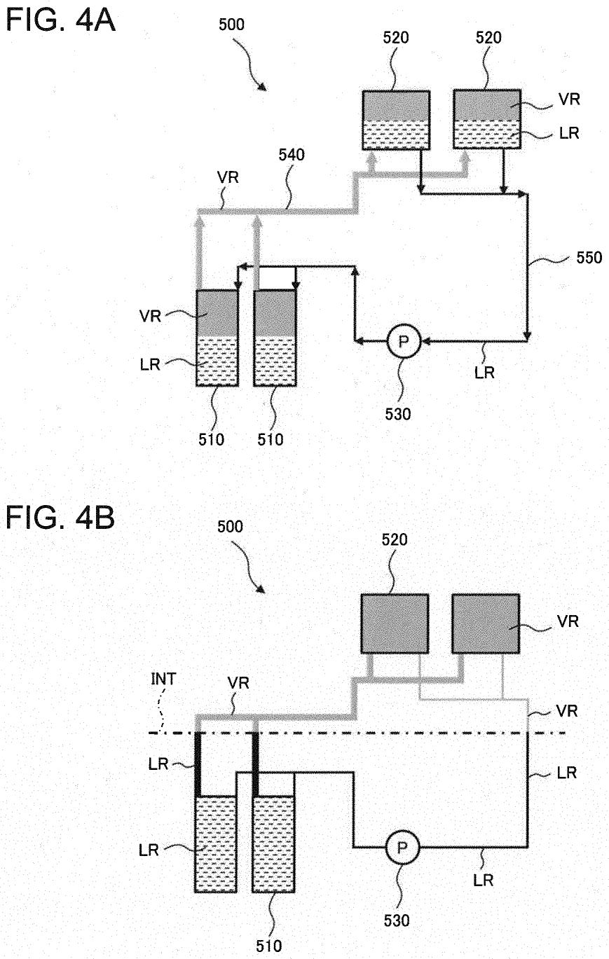

Here, if an amount of the refrigerant liquid within the phase-change cooling system is too large, the pressure of the refrigerant liquid increases. Specifically, for example, as illustrated in FIG. 4B, there is a case where the unnecessary refrigerant liquid that does not evaporate and does not contribute to the heat reception by the latent heat is collected within the steam pipe, and by pressing the refrigerant liquid within the evaporator, the pressure of the refrigerant liquid increases. Further, by the unnecessary refrigerant liquid being collected in the condenser, there is a case where the heat exchange performance at the condenser is lowered, and the pressure within the steam pipe increases. Conversely, also when an amount of the refrigerant liquid is too small, since the heat may not be received sufficiently at the evaporator, the cooling performance is lowered. This means that, in the phase-change cooling system, there exists the proper refrigerant amount at which the heat receiving amount at the evaporator is maximized in the normal operation state.

On the other hand, as described above, there also exists the amount of the refrigerant liquid necessary for shifting the stopped state of the refrigerant liquid driving unit to the normal operation state is present. However, the amount of the refrigerant liquid necessary for shifting the state to the normal operation state does not necessarily coincides with the amount of the refrigerant liquid for maximizing the heat receiving amount at the normal operation state. In other words, generally, an amount L1 of the refrigerant liquid necessary for shifting the stopped state to the normal operation state is larger than an amount L2 of the refrigerant liquid for maximizing the heat receiving amount at the normal operation state (L1>L2).

Even in such a case, since the phase-change cooling system 200 according to the present embodiment is configured to include the refrigerant storage unit 210, an excessive amount of the refrigerant liquid for the normal operation state can be stored in the refrigerant storage unit 210. Specifically, for example, when the above described L1>L2 holds, to the phase-change cooling system 200, the refrigerant liquid in an amount of L1 or above is used. This enables the state of the refrigerant liquid driving unit to be shifted from the stopped state to the normal operation state. Further, after the state is shifted to the normal operation state, the excessive refrigerant liquid is stored in the refrigerant storage unit 210, and thus, the excessive refrigerant liquid is not accumulated in the condenser 120 and the first piping unit 140. Thus, it is possible to prevent the pressure of the refrigerant liquid from rising at the evaporator 110, and the maximization of the heat receiving amount becomes possible.

As above, according to the phase-change cooling system 200 of the present embodiment, even with the configuration of circulating the refrigerant liquid using the driving source, the decrease in the cooling performance immediately after the startup can be avoided and also the heat receiving amount at the normal operation state can be maximized.

Further, the refrigerant storage unit 210 can also absorb a refrigerant liquid that exceeds the amount of the refrigerant liquid at which the heat receiving amount is maximized in the normal operation, and thus, the tolerance in the amount of the refrigerant liquid to be injected to the phase-change cooling system 200 can be improved.

### Third Embodiment

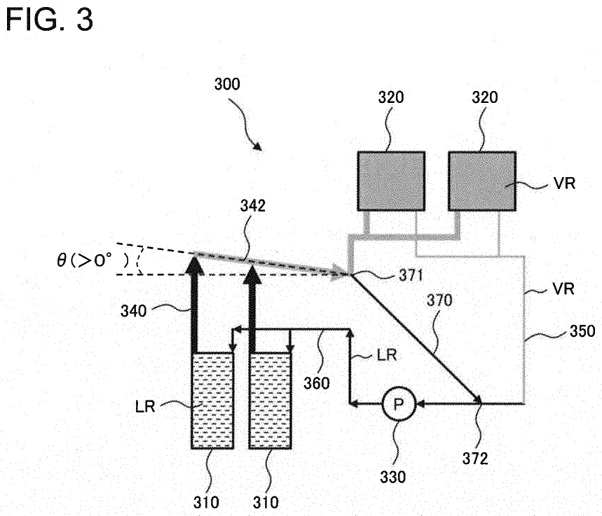

Next, the third embodiment of the present invention is described. FIG. 3 schematically illustrates a configuration of a phase-change cooling system 300 according to the third embodiment of the present invention. Arrows in FIG. 3 represent the refrigerant liquid LR that circulates within the phase-change cooling system 300 when a refrigerant liquid driving unit 330 is started up.

The phase-change cooling system 300 according to the present embodiment includes a plurality of evaporators 310, a condenser 320 and a refrigerant liquid driving unit 330. The phase-change cooling system 300 further includes a first piping unit 340, a second piping unit 350, a third piping unit 360 and a fourth piping unit 370.

The first piping unit 340 connects the plurality of evaporators 310 and the condenser 320. The second piping unit 350 connects the condenser 320 and the refrigerant liquid driving unit 330. The third piping unit 360 connects the refrigerant liquid driving unit 330 and the plurality of evaporators 310.

One end of the fourth piping unit 370 is connected to the first piping unit 340 at the first connection point 371, and the other end the fourth piping unit 370 is connected to the second piping unit 350 at the second connection point 372. The first connection point 371 is positioned at a lower place than a position of an interface between the refrigerant liquid LR and the refrigerant vapor VR retained in the first piping unit 340 at the time when the refrigerant liquid driving unit 330 is started up.

Here, the first piping unit 340 includes, at a part between the plurality of evaporators 310 and the first connection point 371, a common transport unit (common transport means) 342 to which the plurality of evaporators 310 are connected in common. The common transport unit 342 is configured to be inclined such that the side closer to the first connection point 371 is positioned at a lower place than the side closer to the plurality of the evaporators 310. In other words, an angle θ formed by an axis passing the common transport unit 342 and an axis on a horizontal plane is larger than zero degree.

With the above configuration, it is possible to reduce the amount of the refrigerant liquid necessary for shifting the stopped state of the refrigerant liquid driving unit 330 to the normal operation state. The reasons thereof are described below.

When the phase-change cooling system 300 is normally operated, to suppress the pressure drop of the refrigerant vapor VR that flows in the first piping unit 340, the first piping unit 340 is formed from the piping having the large inner diameter and the like. On the other hand, at the time when the refrigerant liquid driving unit 330 is started up, to circulate the refrigerant liquid LR via the fourth piping unit 370, the refrigerant liquid LR needs to be reached to the first connection point 371. In this case, as the first piping unit 340, if the piping having the large inner diameter or the like is used, an amount of the necessary refrigerant liquid increases.

However, the phase-change cooling system 300 according to the present embodiment is configured such that the common transport unit 342 forming part of the first piping unit 340 is inclined downward to the first connection point 371 which is located at a lower place. Therefore, the refrigerant liquid LR can flow within the common transport unit 342 up to the first connection point 371. As a result, it is possible to reduce an amount of the refrigerant liquid necessary for shifting the state to the normal operation state.

The present invention has been described above by assuming the above described embodiments as exemplary examples. However, the present invention is not limited to the above described embodiments. In other words, to the present invention, various aspects that can be understood by a person skilled in the art within the scope of the present invention can be applied.

This application claims priority based on Japanese Patent Application No. 2015-188224 filed on Sep. 25, 2015, the disclosure of which is incorporated herein in its entirety.

### REFERENCE SIGNS LIST

100, 200, 300 Phase-change cooling system
110, 310, 510 Evaporator
120, 320, 520 Condenser
130, 330 Refrigerant liquid driving unit
140, 340 First piping unit
150, 350 Second piping unit
160, 360 Third piping unit
170, 370 Fourth piping unit
171, 371 First connection point
172, 372 Second connection point
210 Refrigerant storage unit
342 Common transport unit
500 Related-art phase-change cooling system
530 Driving source
540 Steam pipe
550 Liquid pipe
LR Refrigerant liquid
VR Refrigerant vapor
INT Gas-liquid interface
INT1, INT2 Interface

1. A phase-change cooling system comprising:
an evaporator holding a refrigerant liquid receiving heat from a heat generating source;
a condenser releasing heat of a refrigerant vapor generated by vaporization of the refrigerant liquid at the evaporator and generating the refrigerant liquid;
refrigerant liquid driving unit circulating the refrigerant liquid;
a first piping unit for connecting the evaporator and the condenser;
a second piping unit connecting the condenser and the refrigerant liquid driving unit;
a third piping unit connecting the refrigerant liquid driving unit and the evaporator; and
a fourth piping unit having one end connected to the first piping unit at a first connection point and another end connected to the second piping unit at a second connection point;
a refrigerant storage unit storing the refrigerant liquid, the refrigerant storage unit being provided within a flow channel formed with the second piping unit; wherein
the first connection point is positioned at a lower place than a position of an interface between the refrigerant liquid and the refrigerant vapor in the first piping unit at a time when the refrigerant liquid driving unit is started up.

2. The phase-change cooling system according to claim 1, wherein
the refrigerant storage unit is arranged in such a way that an interface between the refrigerant liquid and the refrigerant vapor at a time when the refrigerant liquid driving unit is stopped is positioned at a lower place than a top of the refrigerant storage unit.

3. The phase-change cooling system according to claim 1, wherein
the refrigerant storage unit is positioned above the refrigerant liquid driving unit.

4. The phase-change cooling system according to claim 1, wherein
the refrigerant storage unit is positioned at a lower place than the first connection point.

5. The phase-change cooling system according to claim 1, wherein
a plurality of evaporators are included;
the first piping unit includes, at a part between the evaporator and the first connection point, common transport unit to which the plurality of evaporators are connected in common; and
the common transport unit is inclined in such a way that a side of the common transport unit closer to the first connection point is positioned at a lower place than a side of the common transport unit closer to the evaporator.

6. A control method of a phase-change cooling system including:
an evaporator holding a refrigerant liquid receiving heat from a heat generating source;
a condenser releasing heat of a refrigerant vapor generated by vaporization of the refrigerant liquid at the evaporator and generating the refrigerant liquid;
a refrigerant liquid driving unit circulating the refrigerant liquid;
a first piping unit for connecting the evaporator and the condenser;
a second piping unit connecting the condenser and the refrigerant liquid driving unit;
a third piping unit connecting the refrigerant liquid driving unit and the evaporator; and
a fourth piping unit having one end connected to the first piping unit at a first connection point and another end connected to the second piping unit at a second connection point;
the method comprising:
controlling the phase-change cooling system in such a way that a position of an interface between the refrigerant liquid and the refrigerant vapor retained in the first piping unit at a time when the refrigerant liquid driving unit is started up is above the first connection point.
